(19) United States
(12) Patent Application Publication
(10) Pub. No.: US 2019/0378701 A1
(43) Pub. Date: Dec. 12, 2019

(54) DEPOSITION GUARD PLATE AND SPUTTERING DEVICE

(71) Applicant: ULVAC, INC., Chigasaki-shi (JP)

(72) Inventors: Yoshinori Fujii, Chigasaki-shi (JP); Shinya Nakamura, Chigasaki-shi (JP); Kazuyoshi Hashimoto, Chigasaki-shi (JP)

(21) Appl. No.: 16/431,416

(22) Filed: Jun. 4, 2019

(30) Foreign Application Priority Data
Jun. 6, 2018 (JP) 2018-108533

(51) Int. Cl. H01J 37/34; C23C 14/34

(52) U.S. Cl. CPC H01J 37/3488; C23C 14/34

(57) ABSTRACT

A sputtering device includes a vacuum chamber, a target, a substrate stage, and a deposition guard plate. The target is located in the vacuum chamber. The substrate stage is located in the vacuum char and includes a seat surface on which a substrate is placed. The substrate includes an outer circumferential portion extending beyond the seat surface. The deposition guard plate is located in the vacuum chamber and includes an annular inclined surface extending around the substrate stage. The annular inclined surface is faced toward the target and is a circumferential surface of a truncated cone including an inner edge opposing a rear surface of the outer circumferential portion. An angle between the annular inclined surface and a plane including the seat surface is greater than or equal to 10° and less than or equal to 50°.

### CLAIM OF PRIORITY

This application claims the benefit of priority under 35 U.S.C. § 119 to Japanese Application No. 2018-108533, filed on Jun. 6, 2018, Which is incorporated by reference herein in its entirety.

### BACKGROUND

### 1. Field

The following description relates to a deposition guard plate that surrounds a substrate stage and a sputtering device that includes a deposition guard plate.

### 2. Description of Related Art

A sputtering device includes a deposition guard plate to reduce sputtering particles that collect on an inner wall and the like of a vacuum chamber. Some of the sputtering grains are scattered from the deposition guard plate and collected on a substrate as particles. Accordingly, various structures that limit the formation of particles have been suggested for the deposition guard plate and the sputtering device (refer to Japanese Laid-Open Patent Publication No. 2012-224921).

### SUMMARY

Materials used by a sputtering device to form films have shifted from metal elements, which have been conventionally used, to light elements such as carbon. A film of a light element is deposited on a deposition guard plate in the same manner as a film of a metal element. However, a film of a light element is lower in mechanical strength and lower in adhesiveness with the deposition guard plate than a film of a metal element. Thus, a film of a light element is more likely to be scattered from the deposition guard plate than a film of a metal element. Accordingly, the deposition guard plate has room for improvement in terms of limiting the formation of particles on the substrate.

One object of the following description is to provide a deposition guard plate and a sputtering device that limit the formation of particles on a substrate.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a deposition guard plate includes an annular inclined surface extending around a substrate stage. The substrate stage includes a seat surface on which a. substrate is placed. The deposition guard plate is arranged in a vacuum chamber accommodating a target and the substrate stage. The substrate includes an outer circumferential portion extending beyond the seat surface. The annular inclined surface is faced toward the target and is a circumferential surface of a truncated cone including an inner edge opposing a rear surface of the outer circumferential portion. An angle between the annular inclined surface and a plane including the seat surface is greater than or equal to 10° and less than or equal to 50°.

In one general aspect, a sputtering device includes a vacuum chamber, a target, a substrate stage, and a deposition guard plate. The target is located in the vacuum chamber. The substrate stage is located in the vacuum chamber and includes a seat surface on which a substrate is placed. The substrate includes an outer circumferential portion extending beyond the seat surface. The deposition guard plate is located in the vacuum chamber and includes an annular inclined surface extending around the substrate stage. The annular inclined surface is faced toward the target and is a circumferential surface of a truncated cone including an inner edge opposing a rear surface of the outer circumferential portion. An angle between the annular inclined surface and a plane including the seat surface is greater than or equal to 10° and less than or equal to 50°.

With the above structures, the deposition on the annular inclined surface is located outward from the outer circumferential portion of the substrate and easily scattered in a direction in which the annular inclined surface is oriented toward, that is, away from the seat surface toward the radially outer side. This limits the formation of particles on the substrate.

In the above deposition guard plate, a distance between the inner edge and an outer edge of the annular inclined surface in a radial direction of the annular inclined surface may be greater than or equal to 20 mm. Further, in the above sputtering device, a. distance between the inner edge and an outer edge of the annular inclined surface in a radial direction of the annular inclined surface may be greater than or equal to 20 mm.

The deposition scattered from the annular inclined surface may be re-deposit on other components located at the outer side of the annular inclined surface and form particles. In this respect, in the above structures, a range substantially within 20 mm from the outer circumferential portion of the substrate is a range in which the annular inclined surface is located, that is, a range in which scattering of the deposition toward the substrate is limited. The distance the deposition is scattered is limited to approximately 20 mm. Thus, the structure that obtains the limitation range limits a situation in which the deposition scattered toward the outer side of the annular inclined surface is scattered hack to the substrate.

The above deposition guard plate may further include a circumferential wall that gradually rises upward in a vertical direction from an outer edge of the annular inclined surface. Further, in the above sputtering device, the deposition guard plate may further include a circumferential wall that gradually rises upward in a vertical direction from an outer edge of the annular inclined surface. With these structures, the circumferential wall rises upward from the outer edge of the annular inclined surface so that the deposition scattered from the annular inclined surface is easily deposited on the circumferential wall but not easily deposited on the inner wall of the vacuum chamber. Further, the circumferential wall gradually rises upward from the outer edge of the annular inclined surface so that the deposition near a boundary of the annular inclined surface and the circumferential wall is less likely to be delaminated.

In the above sputtering device, the substrate stage is an electrostatic chuck that attracts the substrate with an electrostatic force. The deposition guard plate is a metal plate, and the sputtering device further includes an insulation ring that opposes a rear surface of the outer circumferential portion and is arranged in a gap between the substrate stage and the deposition guard plate in the radial direction of the annular inclined surface.

Components arranged near the electrostatic chuck should be electrically insulated from the electrostatic chuck. In the above structure, the insulation ring provides electrical insulation from the electrostatic chuck and the deposition guard plate limits the formation of particles. This allows the deposition guard plate to have a dedicated structure for limiting the formation of particles.

In another general aspect, a deposition guard plate, which is arranged in a vacuum Chamber, includes a first deposition guard plate and a second deposition guard plate. The first deposition guard plate surrounds a substrate stage located in the vacuum chamber and includes an annular inclined surface inclined diagonally downward from an inner edge to an outer edge. The second deposition guard plate is located above the first deposition guard plate to expose the annular inclined surface. In this structure, the deposition on the annular inclined surface is scattered upward and radially outward from the substrate stage. Thus, the deposition is likely to be scattered in a direction extending radially outward from the substrate stage. This limits the formation of particles on the substrate.

The first deposition guard plate may include a circumferential wall rising upward from the outer edge of the annular inclined surface. In this case, the second deposition guard plate may include an umbrella portion that exposes the annular inclined surface and covers the circumferential wall from above. In this structure, the deposition on the annular inclined surface is scattered toward the inner surface of the second deposition guard plate. Accordingly, the deposition is likely to be scattered in a direction extending radially outward from the substrate stage. This limits the formation of particles on the substrate.

Other features and aspects will be apparent from the following detailed description, the drawings, and the claims.

### BRIEF DESCRIPTION OF THE DRAWINGS

FIG. 1 is a schematic diagram illustrating the structure of a sputtering device in accordance with one embodiment.

FIG. 2 is an enlarged cross-sectional view illustrating part of a substrate stage and a deposition guard plate in accordance with one embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

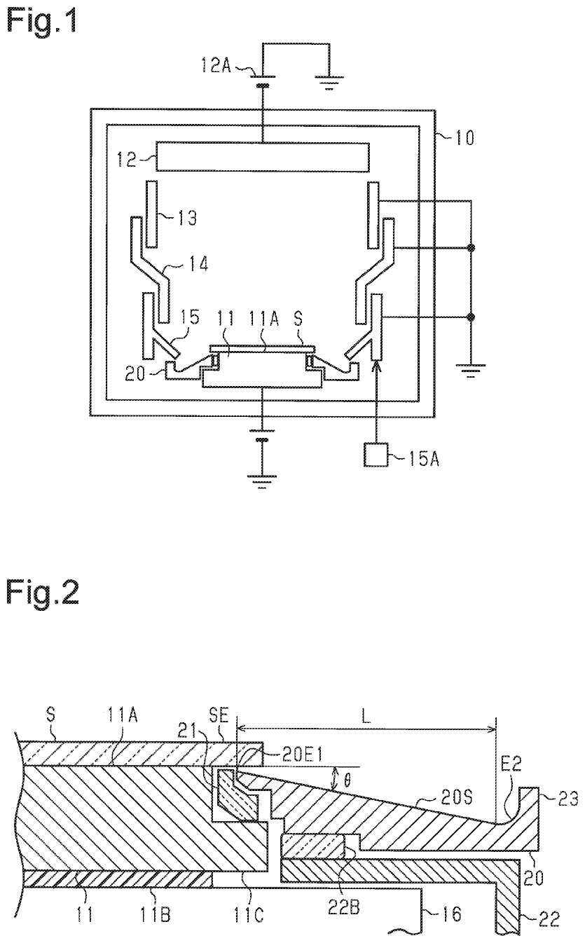

One embodiment of a sputtering device will now be described with reference to FIGS. 1 and 2.

As illustrated in FIG. 1, the sputtering device includes a vacuum chamber 10. The vacuum chamber 10 accommodates a substrate stage 11, a target 12, an earth shield 13, an upper deposition guard plate 14, a middle deposition guard plate 15, and a lower deposition guard plate 20. The vacuum chamber 10, the earth shield 13, and the deposition guard plates 14, 15, and 20 are connected to a ground.

The substrate stage 11 includes a seat surface 11A on which a substrate S is placed. The substrate stage 11 is an electrostatic chuck that attracts the substrate S onto the seat surface 11A with electrostatic force. The substrate S, which is larger than the seat surface 11A, is placed on the seat surface 11A. A portion of the substrate S that extends beyond the seat surface 11A is referred to as an outer circumferential portion SE of the substrate S (refer to FIG. 2).

The target 12 has the form of a disc and opposes the substrate stage 11. The material of the target 12 is, for example, carbon, which is an element lighter than a sputtering gas. The target 12 is connected to a sputtering power source 12A.

The earth shield 13 is cylindrical and extends around the target 12. The earth shield 13 is used as an anode. The sputtering power source 12A applies direct current voltage to the target 12 to plasmatize the sputtering gas drawn into the vacuum chamber 10 and sputter the target 12 with the ion generated in the plasma. Sputtering particles discharged from the target 12 deposit on the surface of the substrate S or inner side walls of the deposition guard plates 14, 15, and 20 and form thin Films of the deposited sputtering particles.

The upper deposition guard plate 14 is cylindrical and surrounds a lower end of the earth shield 13. The middle deposition guard plate 15 is cylindrical and surrounds a lower end of the upper deposition guard plate 14. The lower deposition guard plate 20 is annular and extends around the substrate stage 11. The deposition guard plates 14, 15, and 20 limit the deposition of sputtering particles on inner walls of the vacuum chamber 10. The middle deposition guard plate 15 includes an umbrella portion that covers an outer circumferential portion of the lower deposition guard plate 20 from above. Further, the middle deposition guard plate 15 is connected to a lift mechanism 15A that vertically moves the umbrella portion. The lift mechanism 15A vertically moves the middle deposition guard plate 15 during maintenance of the lower deposition guard plate 20.

As illustrated in FIG. 2, the substrate stage 11 is arranged on a stage support 16 that supports the substrate stage 11. An insulation member 11B is arranged between the substrate stage 11 and the stage support 16 to electrically insulate the substrate stage 11 from the stage support 16. The seat surface 11A is sized such that the outer circumferential portion SE of the substrate S extends beyond the seat surface 11A. The diameter of the substrate S is, for example, 200 mm or 300 mm, and the width of the outer circumferential portion SE in a radial direction is, for example, greater than or equal to 1 mm and less than or equal to 5 mm.

The substrate stage 11 includes a flange 11C that projects outward in the radial direction of the seat surface 11A from an outer circumferential portion of the substrate stage 11. An annular insulation ring 21 is placed on the flange 11C extending around the seat surface 11A.

The sputtering device includes a deposition guard plate support 22 extending around the stage support 16. The lower deposition guard plate 20 is arranged on the deposition guard plate support 22. An insulation member 2B is arranged between the lower deposition guard plate 20 and the deposition guard plate support 22 to electrically insulate the lower deposition guard plate 20 from the deposition guard plate support 22. The lower deposition guard plate 20 is supported by the deposition guard plate support 22. Further, a gap is formed between the lower deposition guard plate 20 and the substrate stage 11. The insulation ring 21 is arranged in the gap between the lower deposition guard plate 20 and the substrate stage 11. The lower deposition guard plate 2C) and the deposition guard plate support 22 are formed, for example, from a metal such as a stainless steel. The insulation ring 21 and the insulation member 22B are formed, for example, from a ceramic such as alumina.

The lower deposition guard plate 20 includes an annular inclined surface 20S faced toward the target 12. The annular inclined surface 20S is a circumferential surface of a truncated cone and includes an inner edge 20E1 that opposes the outer circumferential portion SE of the substrate S. The annular inclined surface 20S has a flat portion in a cross-sectional view that includes the axis of the annular inclined surface 20S. Angle θ between the annular inclined surface 20S and a plane including the seat surface 11A is greater than or equal to 10° and less than or equal to 50°. A distance L between the inner edge 20E1 and an outer edge E2 in the radial direction of the annular inclined surface 20S is greater than or equal to 20 mm. The inner edge 20E1 of the annular inclined surface 20S is located at substantially the same height as the seat surface 11A.

The lower deposition guard plate 20 includes a circumferential wall 23 that gradually rises in the vertical direction from the outer edge E2 of the annular inclined surface 20S. The circumferential wall 23 includes an inner circumferential surface that is smoothly connected to the annular inclined surface 20S. The circumferential wall 23 of the lower deposition guard plate 20 is the portion of the lower deposition guard plate 20 covered by the umbrella portion of the middle deposition guard plate 15 from above.

The sputtering particles discharged from the target 12 are deposited on the annular inclined surface 20S. When films are repeatedly formed on the substrate S, the sputtering particles are intermittently deposited on the annular inclined surface 20S. This intermittently exposes the annular inclined surface 20S to plasma, which is a heat source, and thermally contracts and expands the annular inclined surface 20S in a repetitive manner. Moreover, the gas or particles flowing inside the vacuum chamber 10 continue to strike the deposition on the annular inclined surface 20S. As a result, part of the deposition on the annular inclined surface 20S is scattered from the annular inclined surface 20S. In particular, the deposition of a light element is scattered more easily than a deposition of a heavy element.

The direction in which the deposition is scattered from the annular inclined surface 20S mainly corresponds to the direction in which the annular inclined surface 20S is oriented toward. That is, the deposition is not scattered from the annular inclined surface 20S in an upward direction from the substrate S. Rather, the deposition is scattered in a direction extending from the annular inclined surface 20S toward the inner surface of the middle deposition guard plate 15. Further, the annular inclined surface 20S is oriented radially outward from the outer circumferential portion SE of the substrate S. Thus, the deposition scattered from the annular inclined surface 20S flies away from the seat surface 11A in a direction extending radially outward from the seat surface 11A. That is, the deposition scattered from the annular inclined surface 20S flies away from the substrate S in a direction extending radially outward from the substrate S. As a result, the structure including the lower deposition guard plate 20 limits the formation of particles on the substrate S.

The above embodiment has the advantages described below.

(1) The deposition on the annular inclined surface 20S is likely to be scattered at the outer side of the outer circumferential portion SE of the substrate S in a direction in which the annular inclined surface 20S is oriented toward, that is, in a direction oriented radially outward and away from the seat surface 11A. This limits the formation of particles on the substrate S.

(2) The deposition scattered from the annular inclined surface 20S may be re-deposited on other components located at the outer side of the annular inclined surface 20S thereby causing the formation of particles, in this respect, a range substantially within 20 mm from the outer circumferential portion SE of the substrate S is the range in which the annular inclined surface 20S is located, that is, the range in which scattering of the deposition toward the substrate S is limited. The distance over which the deposition is scattered is limited to approximately 20 mm. Thus, in the structure in which the limitation range extends over distance L, the deposition scattered toward the outer side of the annular inclined surface 20S will not be scattered back to the substrate S.

(3) The circumferential wall 23 of the lower deposition guard plate 20 prevents deposition scattered from the annular inclined surface 20S from collecting on the inner wall of the vacuum chamber 10.

(4) The inner surface of the circumferential wall is smoothly connected to the annular inclined surface 20S thereby limiting delamination of the deposition from the portion that connects the circumferential wall 23 and the annular inclined surface 20S.

The above embodiment may be modified as described below.

The material of the lower deposition guard plate 20 may be changed to an insulative ceramic such as an alumina, which is the material of the insulation ring 21. In this case, the insulation ring 21 may be omitted from the sputtering device. This allows for reduction of the number of components.

The components arranged near the electrostatic chuck should be electrically insulated from the electrostatic chuck. As described above, in the structure in which the insulation ring 21 is located between the substrate stage 11 and the lower deposition guard plate 20, the insulation ring 21 electrically insulates the electrostatic chuck while the lower deposition guard plate 20 limits the formation of particles. This allows the lower deposition guard plate 20 to have a dedicated structure for limiting the formation of particles.

For example, as long as the lower deposition guard plate 20 is made of metal, the dimensional accuracy of angle θ and distance L can be improved more easily than when the lower deposition guard plate 20 is made of ceramic. Further, as long as the lower deposition guard plate 20 is made of metal, roughness can easily be added to the annular inclined surface to increase the adhesion with the deposition.

The substrate stage 11 is not limited to an electrostatic chuck. The substrate stage 11 may be configured to have a structure in which the substrate is fixed to the seat surface by a clamp or have a structure in which the substrate is simply placed on the seat surface.

Distance L in the radial direction of the annular inclined surface 20S may be changed to less than 20 mm. As described above, the structure in which distance L is greater than or equal to 20 mm is preferable from the viewpoint of limiting the formation of particles caused by secondary scattering of the deposition.

The lower deposition guard plate 20 may include a circumferential wall 23 that suddenly rises in the vertical direction from the outer edge E2. Further, the lower deposition guard plate 20 does not have to include the circumferential wall 23. Such structures obtain advantages (1) and (2). The structure in which the inner surface of the circumferential wall 23 is smoothly connected to the annular inclined surface 20S obtains advantages (3) and (4).

The material of the target 12 is not limited to carbon and may be a metal or a metal compound. Even when the material forming the deposition is a metal or a metal compound, scattering of the deposition toward the substrate is limited and the formation of particles on the substrate is limited. Thus, advantage (1) is obtained.

As described above, if the target 12 is formed from a light element such as carbon, the deposition on the lower deposition guard plate 20 is easily scattered. Thus, the inclination of the annular inclined surface 20S at angle θ further limits the formation of particles.

The upper deposition guard plate 14 and the middle deposition guard plate 15 may be integrated into a monolithic structure.

The substrate applied to the sputtering device, for example, is standardized to have a tolerance off 0.2 mm for the diameter of 200 mm. Further, for example, the substrate may be standardized to have a tolerance of ±0.2 mm for the diameter of 300 mm. As described above, the width of the outer circumferential portion SE in the radial direction is, for example, greater than or equal to 1 mm and less than or equal to 5 mm. Thus, the difference of the diameter of the inner edge of the deposition guard plate and the diameter of the substrate is much larger than the tolerance of the substrate diameter and is, for example, greater than or equal to 1 mm and less than or equal to 5 mm.

Technical concepts conceived from the above embodiment and the modified examples will now be described.

### Embodiment 1

A sputtering method for performing sputtering with a sputtering device including:

a vacuum chamber;

a target located in the vacuum chamber;

a substrate stage located in the vacuum chamber and including a seat surface on which a substrate is placed, in which the substrate includes an outer circumferential portion extending beyond the seat surface; and

a deposition guard plate located in the vacuum chamber and includes an annular inclined surface extending around the substrate stage, in which

the annular inclined surface is a circumferential surface of a truncated cone,

an angle formed by the annular inclined surface and a plane including the seat surface is greater than or equal to 10° and less than or equal to 50°, and

the substrate is arranged so that the annular inclined surface is faced toward the target and an inner edge of the annular inclined surface opposes a rear surface of the outer circumferential portion.

The sputtering method according to the embodiment 1 obtains advantage (1).

### Embodiment 2

The sputtering method according to embodiment 1, in which an element forming the target is a light element that is lighter than a sputtering gas.

The deposition formed by an element lighter than the sputtering gas is likely to be scattered when struck by the sputtering gas. In this respect, the sputtering method according to embodiment 2 further limits scattering of the deposition.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is

1. A deposition guard plate comprising:
an annular inclined surface extending around a substrate stage, the substrate stage including a seat surface on which a substrate is placed, wherein
the deposition guard plate is arranged in a vacuum chamber accommodating a target and the substrate stage,
the substrate includes an outer circumferential portion extending beyond the seat surface of the substrate stage,
the annular inclined surface is faced toward the target and is a circumferential surface of a truncated cone including an inner edge opposing a rear surface of the outer circumferential portion of the substrate, and
an angle between the annular inclined surface and a plane including the seat surface is greater than or equal to 10° and less than or equal to 50°.

2. The deposition guard plate according to claim 1, wherein a distance between the inner edge and an outer edge of the annular inclined surface in a radial direction of the annular inclined surface is greater than or equal to 20 mm.

3. The deposition guard plate according to claim 1, further comprising a circumferential wall that gradually rises upward in a vertical direction from an outer edge of the annular inclined surface.

4. A deposition guard plate arranged in a vacuum chamber, the deposition guard plate comprising:
a first deposition guard plate that surrounds a substrate stage located in the vacuum chamber and includes an annular inclined surface inclined diagonally downward from an inner edge to an outer edge of the first deposition guard plate; and
a second deposition guard plate located above the first deposition guard plate to expose the annular inclined surface.

5. The deposition guard plate according to claim 4, wherein
the first deposition guard plate includes a circumferential wall rising upward from the outer edge of the annular inclined surface, and
the second deposition guard plate includes an umbrella portion that exposes the annular inclined surface and covers the circumferential wall from above.

6. A sputtering device, comprising:
a vacuum chamber:
a target located in the vacuum chamber;
a substrate stage located in the vacuum chamber and including a seat surface on which a substrate is placed, wherein the substrate includes an outer circumferential portion extending beyond the seat surface; and
a deposition guard plate located in the vacuum chamber and including an annular inclined surface extending around the substrate stage, wherein
the annular inclined surface is faced toward the target and is a circumferential surface of a truncated cone including an inner edge opposing a rear surface of the outer circumferential portion of the substrate, and
an angle between the annular inclined surface and a plane including the seat surface is greater than or equal to 10° and less than or equal to 50°.

7. The sputtering device according to claim 6, wherein a distance between the inner edge and an outer edge of the annular inclined surface in a radial direction of the annular inclined surface is greater than or equal to 20 mm.

8. The sputtering device according to claim 6, wherein the deposition guard plate further includes a circumferential wall that gradually rises upward in a vertical direction from an outer edge of the annular inclined surface.

9. The sputtering device according to claim 6, wherein
the substrate stage is an electrostatic chuck that attracts the substrate with an electrostatic force,
the deposition guard plate is a metal plate, and
the sputtering device further comprises an insulation ring that opposes a rear surface of the outer circumferential portion and is arranged in a gap between the substrate stage and the deposition guard plate in a radial direction of the annular inclined surface.
